(19) United States
(12) Patent Application Publication
(10) Pub. No.: US 2025/0036019 A1
(43) Pub. Date: Jan. 30, 2025

(54) EUV RETICLE WITH EMBEDDED PROCESS ASSISTANCE LAYER AND METHOD OF MANUFACTURING THE EUV RETICLE

(71) Applicant: Taiwan Semiconductor Manufacturing Co., Ltd., Hsinchu (TW)

(72) Inventors: Sheng-Min WANG, Hsinchu (TW); Ken-Hsien HSIEH, Hsinchu (TW)

(21) Appl. No.: 18/361,609

(22) Filed: Jul. 28, 2023

(51) Int. Cl. G03F 1/24

(52) U.S. Cl. CPC G03F 1/24

(57) ABSTRACT

An extreme ultraviolet (EUV) photolithography reticle includes a substrate and a reflective multilayer on the substrate. The reflective multilayer includes a plurality of stacked first pairs of layers, each pair include a first layer of a first material and a second layer of a second material on the first layer. The reflective multilayer includes a second pair of layers between two of the first pairs and including a first process assistance layer and a third layer of the second material on the process assistance layer. The first material and the second material are selectively etchable with respect to the first process assistance layer. The reticle includes a plurality of first absorption structures extending from a top of the reflective multilayer to the first process assistance layer and configured to absorb extreme ultraviolet light.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

The features in an integrated circuit are produced, in part, with the aid of photolithography. Traditional photolithography techniques include generating a reticle outlining the pattern of features to be formed on an integrated circuit die. The photolithography light source irradiates the integrated circuit die via the reticle. The size of the features that can be produced via photolithography on the integrated circuit die is limited, in part, on the lower end, by the wavelength of light produced by the photolithography light source. Smaller wavelengths of light can produce smaller feature sizes.

Extreme ultraviolet (EUV) photolithography is a photolithography process that employs photolithography light in the EUV region having very small wavelengths. EUV reticles may include a reflective multilayer and a pattern of absorption material. However, it can be difficult to manufacture EUV reticles for increased feature density in wafers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of an EUV photolithography reticle, in accordance with some embodiments.

FIG. 1B is a cross-sectional view of an EUV photolithography reticle, in accordance with some embodiments.

FIG. 1C is a block diagram of an EUV photolithography system, in accordance with some embodiments.

FIGS. 2A and 2B includes graphs associated with an EUV photolithography reticle, in accordance with some embodiments.

FIGS. 3A and 3B includes graphs associated with an EUV photolithography reticle, in accordance with some embodiments.

FIGS. 4A and 4B includes graphs associated with an EUV photolithography reticle, in accordance with some embodiments.

FIGS. 5A-5G are cross-sectional views of an EUV photolithography reticle at various stages of processing, in accordance with some embodiments.

FIGS. 6A-6C are cross-sectional views of an EUV photolithography reticle at various stages of processing, in accordance with some embodiments.

FIG. 7A is a cross-sectional view of an EUV photolithography reticle, in accordance with some embodiments.

FIG. 7B illustrates graphs associated with the photolithography reticle of FIG. 7A, in accordance with some embodiments.

FIG. 8A is a cross-sectional view of an EUV photolithography reticle, in accordance with some embodiments.

FIG. 8B illustrates graphs associated with the photolithography reticle of FIG. 8A, in accordance with some embodiments.

FIG. 9 is a cross-sectional view of an EUV photolithography reticle, in accordance with some embodiments.

FIG. 10 is a cross-sectional view of an EUV photolithography reticle, in accordance with some embodiments.

FIG. 11 is a cross-sectional view of an EUV photolithography reticle, in accordance with some embodiments.

FIG. 12 is a cross-sectional view of an EUV photolithography reticle, in accordance with some embodiments.

FIG. 13 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

Extreme ultraviolet (EUV) light is used to produce particularly small features due to the relatively short wavelength of EUV light. In particular, high numerical aperture (NA) EUV exposure is adopted for finer resolution. However, in high NA scanners, the depth of focus becomes narrower. Accordingly, the best focus range of printing patterns may need to be carefully controlled. One solution is adopting an EUV photolithography reticle (or mask) with a reflective multilayer that has been etched and in which an absorption material is embedded to reduce reticle induced imaging aberrations known as mask 3D (M3D) effects. One possible solution is to embed an etch-stop layer in the reflective multilayer to stop the etching process prior to formation of the absorption material. However directly inserting an etch-stop layer may degrade the reflectance of the reflective multilayer, thereby reducing the throughput of exposure.

Embodiments of the disclosure are able to embed a process assistance layer, such as an etch-stop layer or an implant-stop layer, in a reflective multilayer of an EUV reticle while retaining high levels of reflectivity of the reflective multilayer. The reflective multilayer includes a plurality of pairs of layers. The pairs of layers are stacked on each other. Most of the pairs of layers have a first layer of a first material stacked on a second layer of a second material. However, in one of the pairs of layers process assistance layers the second layer is not made of the second material but is instead made of a process assistance material that functions as a process assistance layer. In an example in which the process assistance layer is an etch-stop layer, the process assistance layer has a material that is not etched by an etching process that etches the first and second layers of the other pairs of layers. In other words, the first material and the second material of the pairs of layers are selectively etchable with respect to the material of the etch-stop layer. In an example in which the process assistance layer is an implant-stop layer, the process assistance layer includes material that does not permit dopants of a dopant implantation process the past to layers below the process assistance layer.

The material, thickness, refracted index, an extinction coefficient are selected to maintain high reflectivity of the reflective multilayer. The result is that a process assistance layer can be utilized without negatively impacting the reflectivity of the reflective multilayer. This enables absorption patterns of the reticle to be formed by etching patterns in the reflective multilayer or by implanting absorptive ions into the reflective multilayer in a desired pattern. EUV processes remain effective. Wafers formed by the EUV processes have higher wafer yields and results in properly functioning integrated circuits.

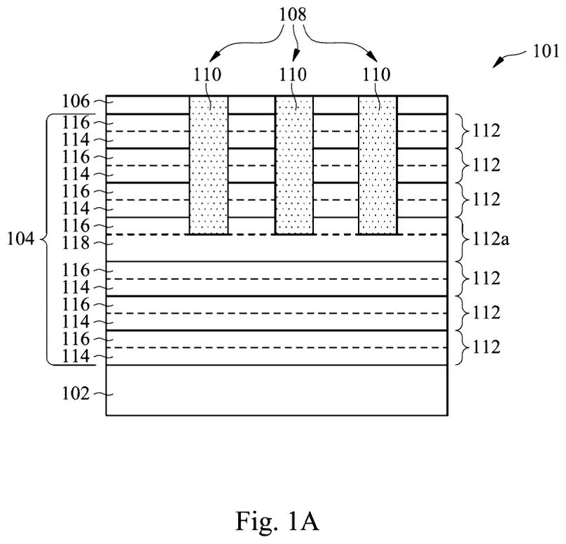

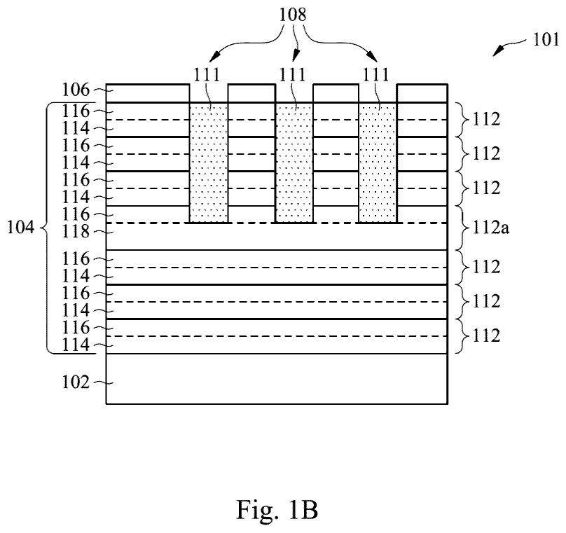

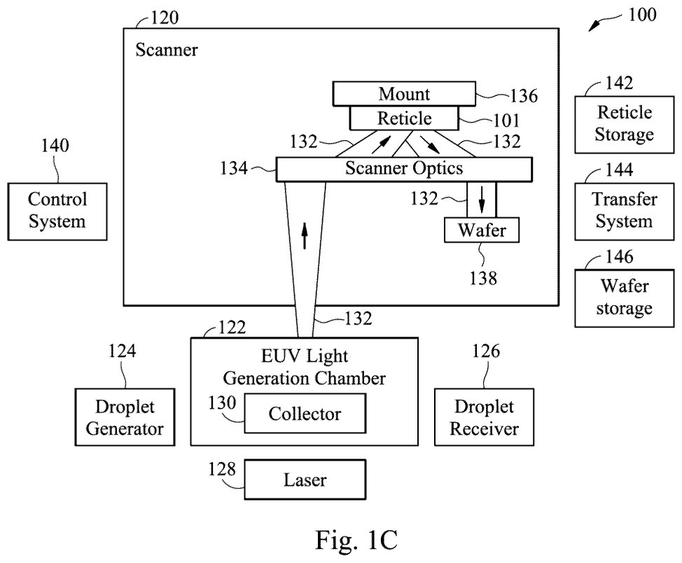

FIG. 1A is a cross-sectional view of an EUV photolithography reticle 101, in accordance with some embodiments. The EUV photolithography reticle 101 includes a substrate 102, a reflective multilayer 104 on the substrate 102, a buffer layer 106 on the reflective multilayer, and a pattern 108 of absorption structures 110 of absorption material embedded in trenches within the reflective multilayer. As will be set forth in more detail below, the reflective multilayer 104 includes a process assistance layer that enables safe etching of the reflective multilayer 104 in order to form the pattern 108 of the absorption structures 110 of absorption material in the reflective multilayer 104.

The substrate 102 includes a low thermal expansion material. The low thermal expansion material substrate 102 serves to minimize image distortion due to heating of the reticle 101. The low thermal expansion material substrate 102 can include materials with a low defect level and a smooth surface. In some embodiments, the substrate 102 includes SiO₂. The substrate 102 can be doped with titanium dioxide. The substrate 102 can include other low thermal expansion materials than those described above without departing from the scope of the present disclosure.

Though not shown herein, in one embodiment the substrate 102 may be positioned on a conductive layer. The conductive layer can assist in electrostatically chucking the reticle 101 during fabrication and use of the reticle 101. In one embodiment, the conductive layer includes chromium nitride. The conductive layer can include other materials without departing from the scope of the present disclosure.

The reticle 101 includes a reflective multilayer 104. The reflective multilayer 104 is positioned on the substrate 102. The reflective multilayer 104 is configured to reflect the extreme ultraviolet light during photolithography processes in which the reticle 101 is used. The reflective properties of the reflective multilayer 104 are described in more detail below.

In one embodiment, the reflective multilayer 104 operates in accordance with reflective properties of the interface between two materials. In particular, reflection of light will occur when light is incident at the interface between two materials of different refractive indices. A greater portion of the light is reflected when the difference in refractive indices is larger.

One technique to increase the proportion of reflected light is to include a plurality of interfaces by depositing a multilayer of alternating materials. The properties and dimensions of the materials can be selected so that constructive interference occurs with light reflected from different interfaces. However, the absorption properties of the employed materials for the plurality of layers may limit the reflectivity that can be achieved.

Accordingly, the reflective multilayer 104 includes a plurality of pairs of layers 112. Each pair of layers 112 includes a first layer 114 of a first material and a second layer 116 of a second material. The materials and thicknesses of the first layer 114 and the second layer 116 are selected to promote reflection and constructive interference of extreme ultraviolet light.

In some embodiments, the first layer 114 is a layer of conductive material. In one example, the first layer 114 is molybdenum and has a thickness between 2 nm and 4 nm. In one embodiment, the first layer 114 of molybdenum has a thickness of about 3 nm. Other materials and thicknesses can be utilized for the first layer 114 without departing from the scope of the present disclosure.

In some embodiments, the second layer 116 is a layer of semiconductor material. In one example, the second layer 116 is silicon and has a thickness between 3 nm and 5 nm. In one embodiment, the thickness of the second layer 116 is about 4 nm. Other materials and thicknesses can be utilized for the second layer 116 without departing from the scope of the present disclosure.

The thicknesses of the layers in the reflective multilayer 104 are selected based on the expected wavelength of extreme ultraviolet light used in the photolithography processes and the expected angle of incidence of the extreme ultraviolet light during the photolithography processes. The wavelength of the extreme ultraviolet light is between 1 nm and 20 nm. in one embodiment, the central wavelength of the EUV light is 13.5 nm., The number of pairs of layers is between 20 pairs of layers and 60 pairs of layers, according to one embodiment. Other materials, thicknesses, numbers of pairs, and configurations of layers in the reflective multilayer 104 can be utilized without departing from the scope of the present disclosure. Other wavelengths of extreme ultraviolet light can be used without departing from the scope of the present disclosure.

In a particular example disclosed herein, the first layer 114 is molybdenum with a thickness of about 3 nm and the second layer 116 is silicon with a thickness of about 4 nm, the wavelength of the EUV light is 13.5 nm, in the number of pairs of layers 112 is 40. This results in a high level of reflectivity and very effective EUV photolithography processes. However, other configurations of materials, thicknesses, wavelengths, and pairs of layers can be utilized without departing from the scope of the present disclosure.

The reflective multilayer 104 includes a pair of layers 112a embedded among the pairs of layers 112. For simplicity, in FIG. 1A there are three pairs of layers 112 below the pair of layers 112a and there are three pairs of layers 112 above the pair of layers 112a. However, as noted above, in practice there may be a much higher number of pairs of layers 112 than are shown in FIG. 1A.

In one embodiment, the pair of layers 112a is a process assistance pair. As used herein, the term “process assistance pair” or “process assistance layer” corresponds to a pair of layers or a layer that plays a particular role in forming the pattern of the reticle 101 without detracting from the reflectivity of the reflective multilayer 104.

The pair of layers 112a includes a process assistance layer 118 and the second layer 116. In some embodiments, the second layer 116 of the pair of layers 112a is the same material and thickness as the second layer 116 of the pairs 112. However, the process assistance layer 118 is a different material than the material of the first layer 114 of the pairs 112. In the example of FIG. 1A, the process assistance layer 118 is an etch-stop layer. The material of the process assistance layer 118 is selected so that the material of the first layer 114 and the material of the second layer 116 are selectively etchable with respect to the process assistance layer 118. This enables the process assistance layer 118 can be utilized as an etch-stop layer. Before providing further discussion of the properties of the process assistance layer 118, it is beneficial to discuss aspects of the pattern 108.

The reticle 101 includes a selected pattern 108. When EUV light is incident on the reticle 101 during a photolithography process, some of the EUV light will be reflected from the reflective multilayer 104 and eventually passed to the surface of a wafer on which a photolithography process has been performed. Further details about the photolithography process are provided in relation to FIG. 1C. As can be seen in FIG. 1A, trenches have been formed in the reflective multilayer 104 and filled with an absorption material to form absorption structures 110. The pattern of the trenches and corresponding absorption structures 110 of absorption material 110 corresponds to the pattern 108 of the EUV reticle 101. Just as some of the EUV light will be reflected from the reflective multilayer 104 during an EUV photolithography process, some of the light will be absorbed by the absorption material 110. The result is that reflected light carries a pattern based on the pattern 108. Each absorption structure extends from the top of the reflective multilayer 104 to the process assistance layer 118.

While in some solutions the absorption material may be formed and patterned entirely above the reflective multilayer 104 without forming trenches in the reflective multilayer 104, there are benefits to forming the absorption structure in trenches in the reflective multilayer 104. For example, the M3D affect and other types of imaging aberrations may be reduced by including the absorption structures 110 in trenches in the reflective multilayer 104.

However, there are risks to forming trenches in the reflective multilayer 104. For example, if the etching depth is not carefully controlled then the reflectivity of the reflective multilayer 104 may be reduced. Furthermore, the ability of the reticle 101 to impart a pattern to the EUV light may be inhibited.

In one possible solution, an etch-stop layer may be inserted in the reflective multilayer between pairs of layers as a single layer between pairs of layers. However, insertion of an etch-stop layer between pairs of layers may significantly decrease the overall reflectivity of the reflective multilayer.

Embodiments of the present disclosure utilize the process assistance layer 118 (the etch-stop layer in the example of FIG. 1A), as a substitute for the layer 114 in one of the pairs 112, resulting in the pair 112a. Accordingly, the process assistance layer 118 is also part of a pair that includes the layer 116 identically to the other pairs 112. This is highly beneficial in that carefully selecting the material and thickness, as well as the depth of placement of the process assistance layer 118 results in maintaining a very high reflectivity of the reflective multilayer 104. In some embodiments, the refractive index of the process assistance layer 118 is between 0.85 to 1.2 in the EUV band. In some embodiments, the extinction coefficient of the process assistance layer is between 0 and 0.1 in the EUV band. In some embodiments, the thickness of the process-assistance layer 118 is between 0.1 nm and 20 nm. Other refractive indices, extinction coefficients, and thicknesses can be utilized without departing from the scope of the present disclosure.

Because the process assistance layer 118 is in a pair 112a above a pair 112, the process assistance layer 118 is embedded directly between two layers 116. The top surface of the process assistance layer 118 is in contact with the bottom surface of the layer 116 of the pair 112a. The bottom surface of the process assistance layer 118 is in contact with the top surface of the layer 116 of the pair 112 directly below the pair 112a.

In some embodiments, the process assistance layer 118 includes ruthenium. Continue with an example in which the first layer 114 is molybdenum with a thickness of 3 nm and the second layer is silicon with a thickness of 4 nm, the process assistance layer 118 may include ruthenium with a thickness between 2 nm and 3 nm. In some embodiments, the process assistance layer 118 may include ruthenium with a thickness of about 2.3 nm. This results in a very high reflectivity of the reflective multilayer 104. However, the process assistance layer 118 may have other materials and thicknesses without departing from the scope of the present disclosure.

The buffer layer 106 is positioned on the reflective multilayer 104. The buffer layer 106 may protect the reflective multilayer during etching processes that form the trenches in for the absorption structures 110. Prior to etching trenches in the reflective multilayer 104 for the pattern 108, the buffer layer 106 is first patterned in accordance with the pattern 108 utilizing a first etching process. After the buffer layer 106 is patterned, the trenches can then be formed in the reflective multilayer 104 in a second etching process. During the second etching process, the buffer layer 106 protects the portions of the reflective multilayer 104 that are directly below the buffer layer 106.

In some embodiments, the buffer layer 106 includes ruthenium. Accordingly, in some embodiments, the buffer layer 106 is a same material as the process assistance layer 118. In some embodiments, the buffer layer 104 has a thickness between 3 nm and 4 nm. The buffer layer 106 can include compounds of ruthenium including ruthenium boride and ruthenium silicide. The buffer layer can include chromium, chromium oxide, or chromium nitride. The buffer layer 106 can be deposited by a low temperature deposition process to prevent diffusion of the buffer layer 106 into the reflective multilayer 104. Other materials, deposition processes, and thicknesses can be utilized for the buffer layer 106 without departing from the scope of the present disclosure.

The material of the absorption structures 110 is selected to have a high absorption coefficient for wavelengths of extreme ultraviolet radiation that will be used in the photolithography processes with the reticle 101. In other words, the materials of the absorption structures 110 are selected to absorb extreme ultraviolet radiation. In one embodiment, the absorption material includes material selected from a group including chromium, chromium oxide, titanium nitride, tantalum nitride, tantalum, titanium, aluminum-copper, palladium, tantalum boron nitride, tantalum boron oxide, aluminum oxide, or other suitable materials. Other materials and thicknesses can be used for the absorption material without departing from the scope of the present disclosure.

FIG. 1B is a cross-sectional view of the EUV reticle 101, in accordance with some embodiments. The EUV reticle 101 of FIG. 1B is substantially similar to the EUV reticle 101 of FIG. 1A in many regards. The EUV reticle 101 of FIG. 1B may differ in that the pattern 108 is not formed by etching the reflective multilayer 104 in order to form trenches in which absorption structures 110 may be placed. Instead, the pattern 108 is implemented by first patterning the buffer layer 106 and then performing a dopant implantation process. The dopant implantation process implants dopant species into the reflective multilayer 104. The dopant species can include Ta, Cr, Pt, Pd, Ir, Ru, Ni, or other suitable dopant species. The dopant implantation process causes the areas below the openings in the buffer layer 106 to become absorptive to EUV light. In other words, absorption structures 111 of absorption material formed in the reflective multilayer 104 via dopant implantation.

The EUV reticle 101 of FIG. 1B may differ in that the material of the process assistance layer 118 may be different than in FIG. 1A. In particular, the material of the process assistance layer 118 is selected to ensure that dopant species do not pass through the process assistance layer 118 into the pairs of layers 112 below the process assistance layer 118.

In some embodiments, the process assistance layer 118 can include SiO2. In some embodiments, the process assistance layer 118 is between 2 nm and 3 nm in thickness. In the example in which the layer 116 is silicon with a thickness of 4 nm, the layer 114 is molybdenum with a thickness of 3 nm, and the EUV light has a wavelength of 13.5 nm, the process assistance layer 118 may have a thickness of 2.2 nm. This results in maintaining a high reflectivity of the reflective multilayer 104. Other materials and thicknesses can be utilized for the process assistance layer 118 without departing from the scope of the present disclosure.

FIG. 1C is a block diagram of an EUV photolithography system 100, according to some embodiments. The components of the EUV photolithography system 100 cooperate to perform photolithography processes. As will be set forth in more detail below, the photolithography system 100 utilizes a reticle 101 including a process assistance layer 118 as described in relation to FIGS. 1A and 1B in order to pattern a wafer during a photolithography process. As used herein, the terms “EUV light” and “EUV radiation” can be used interchangeably.

The EUV photolithography system 100 includes a droplet generator 124, an EUV light generation chamber 122, a droplet receiver 126, a scanner 120, and a laser 128. The droplet generator 124 outputs droplets into the EUV light generation chamber 122. The laser 128 irradiates the droplets with pulses of laser light within the EUV light generation chamber 122. The irradiated droplets emit EUV light 132. The EUV light 132 is collected by a collector 130 and reflected toward the scanner 120. The scanner 120 conditions the EUV light 132, reflects the EUV light 132 off of a reticle 101 including a mask pattern, and focuses the EUV light 132 onto the wafer 138. The EUV light 132 patterns a layer on the wafer 138 in accordance with a pattern of the reticle 101. Each of these processes is described in more detail below.

The droplet generator 124 generates and outputs a stream of droplets. The droplets can include tin, though droplets of other material can be utilized without departing from the scope of the present disclosure. The droplets move at a high rate of speed toward the droplet receiver 126. The droplets have an average velocity between 60 m/s to 200 m/s. The droplets have a diameter between 10 μm and 200 μm. The generator may output between 1000 and 100000 droplets per second. The droplet generator 124 can generate droplets having different initial velocities and diameters than those described above without departing from the scope of the present disclosure.

In some embodiments, the EUV light generation chamber 122 is a laser produced plasma (LPP) EUV light generation system. As the droplets travel through the EUV light generation chamber 122 between the droplet generator 124 and the droplet receiver 126, the droplets are irradiated by the laser 128. When a droplet is irradiated by the laser 128, the energy from the laser 128 causes the droplet to form a plasma. The plasmatized droplets generate EUV light 132. This EUV light 132 is collected by the collector 130 and passed to the scanner 120 and then on to the wafer 138.

In some embodiments, the laser 128 is positioned external to the EUV light generation chamber 122. During operation, the laser 128 outputs pulses of laser light into the EUV light generation chamber 122. The pulses of laser light are focused on a point through which the droplets pass on their way from the droplet generator 124 to the droplet receiver 126. Each pulse of laser light is received by a droplet. When the droplet receives the pulse of laser light, the energy from the laser pulse generates a high-energy plasma from the droplet. The high-energy plasma outputs EUV light 132.

In some embodiments, the laser 128 irradiates the droplet with two pulses. A first pulse causes the droplet to flatten into a disk like shape. The second pulse causes the droplet to form a high temperature plasma. The second pulse is significantly more powerful than the first pulse. The laser 128 and the droplet generator 124 are calibrated so that the laser emits pairs of pulses such that the droplet is irradiated with a pair of pulses. The laser can irradiate droplets in a manner other than described above without departing from the scope of the present disclosure. For example, the laser 128 may irradiate each droplet with a single pulse or with more pulses than two. In some embodiments, there are two separate lasers. A first laser delivers the flattening pulse. A second laser delivers the plasmatizing pulse.

In some embodiments, the light output by the droplets scatters randomly in many directions. The photolithography system 100 utilizes the collector 130 to collect the scattered EUV light 132 from the plasma and direct or output the EUV light 132 toward the scanner 120.

The scanner 120 includes scanner optics 134. The scanner optics 134 include a series of optical conditioning devices to direct the EUV light 132 to the reticle. The scanner optics 134 may include refractive optics such as a lens or a lens system having multiple lenses (zone plates). The scanner optics 134 may include reflective optics, such as a single mirror or a mirror system having multiple mirrors. The scanner optics 134 direct the ultraviolet light from the EUV light generation chamber 122 to a reticle 101. FIG. 1A illustrates the reticle 101 coupled to a mount 136. The mount 136 holds the reticle 101 during exposure to EUV light in the photolithography process.

During an EUV exposure process, EUV light 132 reflects off of the reticle 101 back toward further optical features of the scanner optics 134. In some embodiments, the scanner optics 134 include a projection optics box. The projection optics box may have refractive optics, reflective optics, or combination of refractive and reflective optics. The projection optics box directs the EUV light 132 onto the wafer 138, for example, a semiconductor wafer.

The EUV light 132 includes a pattern from the reticle 101. In particular, the reticle 101 includes the pattern to be defined in the wafer 138. After the EUV light 132 reflects off of the reticle 101, the EUV light 132 contains the pattern of the reticle 101. A layer of photoresist typically covers the wafer 138 during extreme ultraviolet photolithography irradiation. The photoresist assists in patterning a surface of the semiconductor wafer 138 in accordance with the pattern of the reticle. In some embodiments, a high-NA EUV exposure is adopted to obtain finer resolution in forming patterns for metal lines (or other features) on a wafer 138.

In some embodiments, the EUV photolithography system 100 includes a control system 140. The control system 140 is communicatively coupled to the droplet generator 124 and the laser 128. The control system 140 can control the operation of the droplet generator 124 and the laser 128. The control system 140 can adjust operating parameters of the droplet generator 124 and the laser 128. Accordingly, the control system 140 controls the performance of EUV exposure processes.

In some embodiments, the control system 140 is also communicatively coupled to the mount 136 that holds the wafer 138. The wafer mount can be translated via one or more motors or other types of motivator units under control of the control system 140. A plurality of integrated circuits may be formed on the wafer 138.

The EUV system 100 includes a reticle storage 142. The reticle storage 142 may include storage and protection pods that enclose and protect the reticle 101 when the reticle 101 is not in use. After the reticle 101 have been initially manufactured, the reticle 101 may immediately be enclosed in the reticle storage 142. The reticle 101 remains in the reticle storage 142 during transport from the manufacturing site to the wafer processing site. The reticle storage 142 may provide very strong protection against contaminants when the reticle 101 is not in use.

The reticle 101 may remain in the reticle storage 142 until the reticle 101 is to be utilized in the EUV photolithography process. At this time, the reticle 101 is transferred from the reticle storage 142 into the scanner 120. The reticle storage 142, or portions of the reticle storage 142 may be carried into the scanner 120. The reticle 101 is then unloaded from the reticle storage onto the mount 136, in turn, for the EUV photolithography process. After the EUV photolithography process, the reticle 101 is unloaded from the mount 136 to the reticle storage 142.

The EUV photolithography system 100 may also include a wafer storage 146. The wafer storage 146 stores wafers 138 when the wafers are not in use. The wafer storage 146 may include storage for wafers 138 that have yet to be transferred into the scanner 120 for patterning. The wafer storage may include storage for wafers 138 that have already been patterned within the scanner 120.

The EUV system 100 includes a transfer system 144. The transfer system 144 may include one or more robot arms. The one or more robot arms can transfer the reticle 101 between the scanner 120, the reticle storage 142, a reticle scanner, and a reticle cleaning station. The one or more robot arms can also transfer wafers 138 between the scanner 120 and the wafer storage 146. In some embodiments, robot arms that transfer wafers 138 are separate from robot arms that transfer the reticle 101. The EUV system 100 can include other types of reticle transport systems without departing from the scope of the present disclosure.

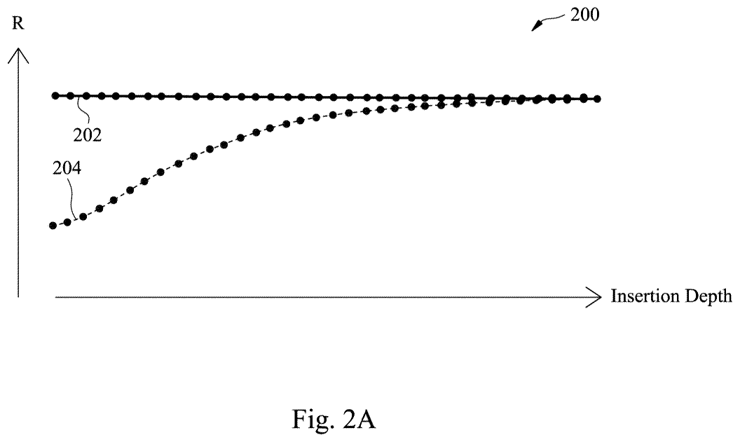

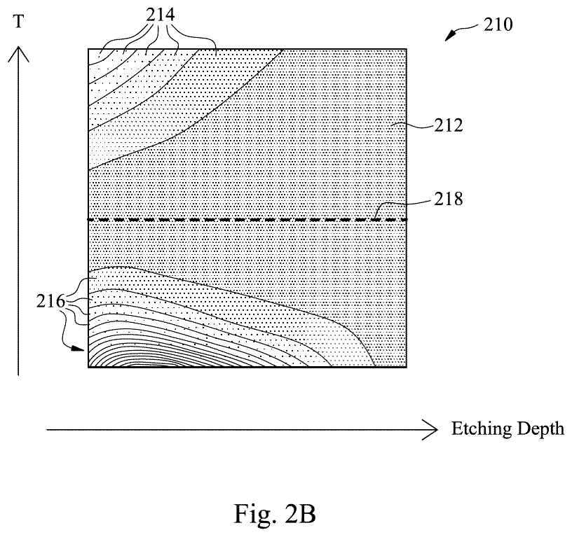

FIG. 2A includes a graph 200 associated with a reticle 101, in accordance with some embodiments. The vertical axis of the graph 200 corresponds to the reflectivity R of the reflective multilayer 104 that includes a process assistance layer 118. The horizontal axis of the graph 200 corresponds to the insertion depth of the process assistance layer 118 within the reflective multilayer 104.

The graph 200 includes a curve 202 and a curve 204. The curve 202 corresponds to reflectivity for the reflective multilayer 104 in which the process assistance layer 118 is part of a process assistance pair 112a as described in relation to FIGS. 1A and 1B. In one embodiment, the curve 204 corresponds to reflectivity for the reflective multilayer 104 in which a process assistance layer 118 is embedded singly between two pairs of layers. As can be seen, the reflectivity is high for all insertion depths for the curve 202. The reflectivity for the curve 204 is considerably lower unless the process assistance layer 118 is embedded very near the bottom of the reflective multilayer 104. In some embodiments, the graph 200 corresponds to the reflectivity for the example in which the layer 116 is silicon with a thickness of 4 nm, layer 114 is molybdenum with a thickness of 3 nm, and the process assistance layer 118 is ruthenium with a thickness of 2.3 nm. In some embodiments, the reflectivity is greater than 0.7.

FIG. 2B is a graph 210 associated with the graph 200 of FIG. 2A, in accordance with some embodiments. The vertical axis corresponds to the thickness of the process assistance layer 118. The horizontal axis corresponds to the etching depth or the depth of placement of the process assistance layer 118. The graph 210 illustrates a high reflectance area 212, and lower reflectance areas 214 and 216. The line 218 corresponds to the selected thickness of the process assistance layer 118 (2.3 nm, in one example) as this selected thickness results in high reflectivity for all etching depths.

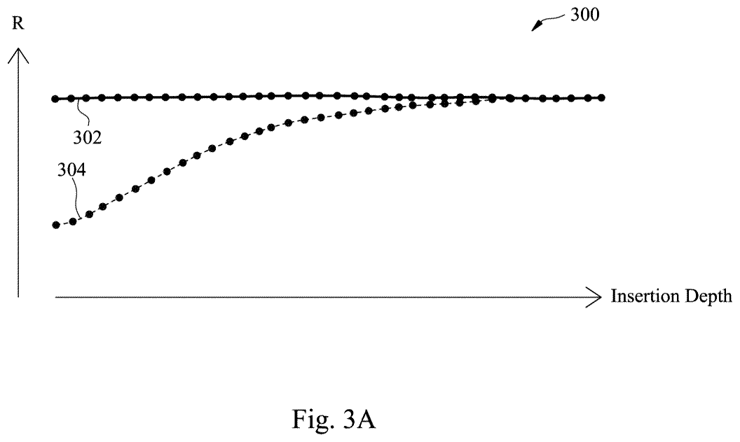

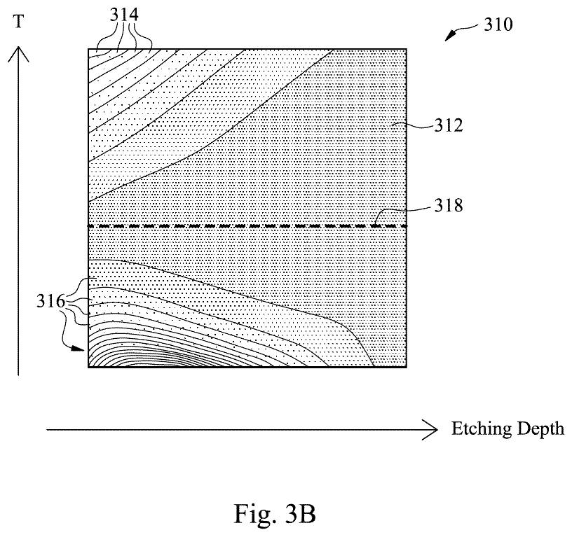

FIG. 3A includes a graph 300 associated with a reticle 101, in accordance with some embodiments. The vertical axis of the graph 300 corresponds to the reflectivity R of the reflective multilayer 104 that includes a process assistance layer 118. The horizontal axis of the graph 300 corresponds to the insertion depth of the process assistance layer 118 within the reflective multilayer 104.

The graph 300 includes a curve 302 and a curve 304. The curve 302 corresponds to reflectivity for the reflective multilayer 104 in which the process assistance layer 118 is part of a process assistance pair 112a as described in relation to FIGS. 1A and 1B. In one embodiment, the curve 304 corresponds to reflectivity for the reflective multilayer 104 in which a process assistance layer 118 is embedded singly between two pairs of layers. As can be seen, the reflectivity is high for most insertion depths for the curve 302. The reflectivity for the curve 304 is considerably lower unless the process assistance layer 118 is embedded very near the bottom of the reflective multilayer 104. In some embodiments, the graph 300 corresponds to the reflectivity for the example in which the layer 116 is silicon with a thickness of 4 nm, layer 114 is molybdenum with a thickness of 3 nm, and the process assistance layer 118 is SiO2 with a thickness of 2.2 nm.

FIG. 3B is a graph 310 associated with the graph 300 of FIG. 3A, in accordance with some embodiments. The vertical axis corresponds to the thickness of the process assistance layer 118. The horizontal axis corresponds to the etching depth or the depth of placement of the process assistance layer 118. The graph 310 illustrates a high reflectance area 312, and lower reflectance areas 314 and 316. The line 318 corresponds to the selected thickness of the process assistance layer 118 (2.2 nm, in one example) as this selected thickness results in high reflectivity for all etching depths.

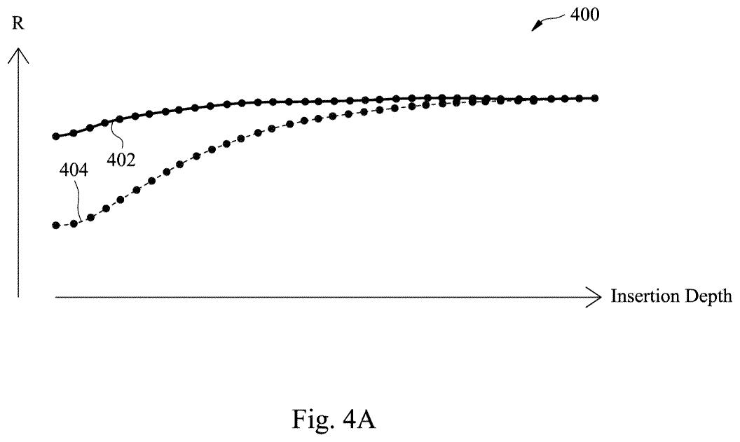

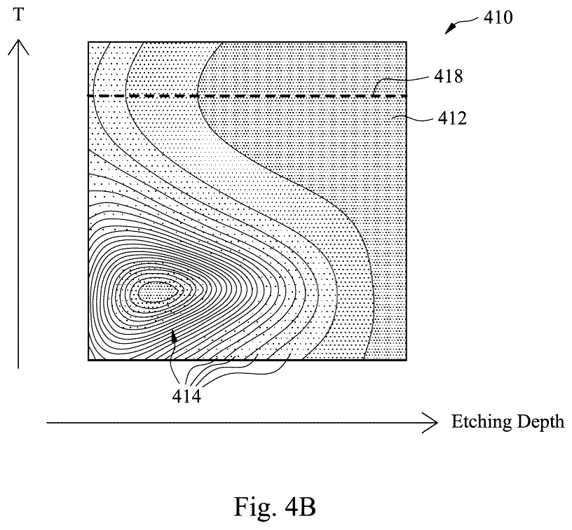

FIG. 4A includes a graph 400 associated with a reticle 101, in accordance with some embodiments. The vertical axis of the graph 400 corresponds to the reflectivity R of the reflective multilayer 104 that includes a process assistance layer 118. The horizontal axis of the graph 400 corresponds to the insertion depth of the process assistance layer 118 within the reflective multilayer 104.

The graph 400 includes a curve 402 and a curve 404. The curve 402 corresponds to reflectivity for the reflective multilayer 104 in which the process assistance layer 118 is part of a process assistance pair 112a as described in relation to FIGS. 1A and 1B. In one embodiment, the curve 404 corresponds to reflectivity for the reflective multilayer 104 in which a process assistance layer 118 is embedded singly between two pairs of layers. As can be seen, the reflectivity is high for most insertion depths for the curve 402. The reflectivity for the curve 404 is considerably lower unless the process assistance layer 118 is embedded very near the bottom of the reflective multilayer 104. In some embodiments, the graph 400 corresponds to the reflectivity for the example in which the layer 116 is silicon with a thickness of 4 nm, layer 114 is molybdenum with a thickness of 3 nm, and the process assistance layer 118 is ruthenium with a thickness of 4.2 nm.

FIG. 4B is a graph 410 associated with the graph 400 of FIG. 4A, in accordance with some embodiments. The vertical axis corresponds to the thickness of the process assistance layer 118. The horizontal axis corresponds to the etching depth or the depth of placement of the process assistance layer 118. The graph 410 illustrates a high reflectance area 412 and lower reflectance areas 414. The line 418 corresponds to the selected thickness of the process assistance layer 118 (4.2 nm, in one example) as this selected thickness results in high reflectivity for most etching depths.

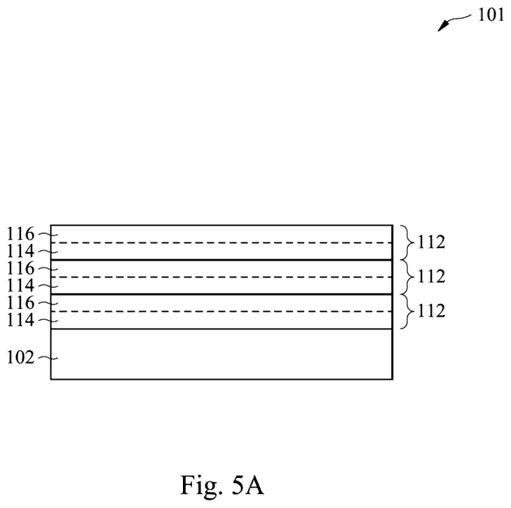

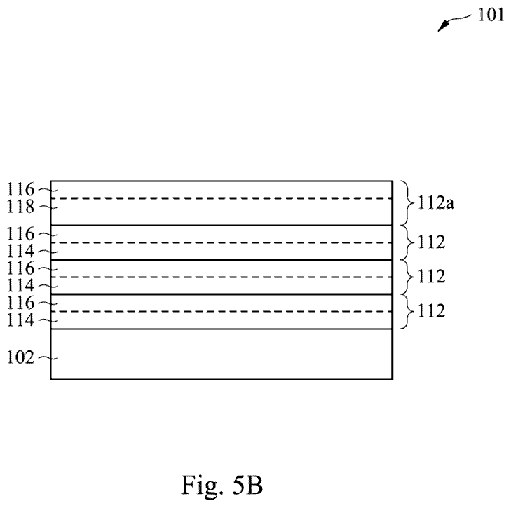

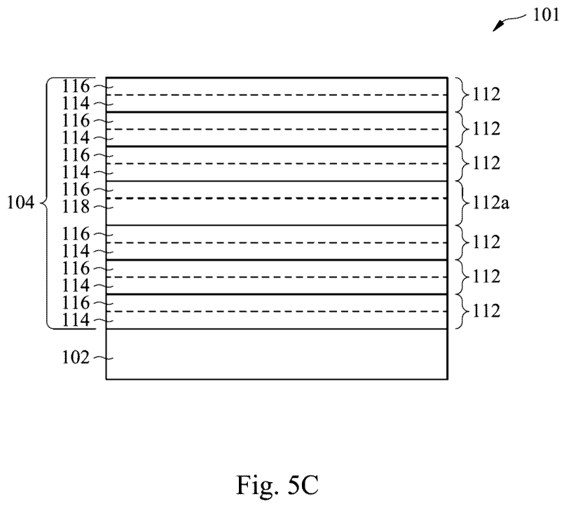

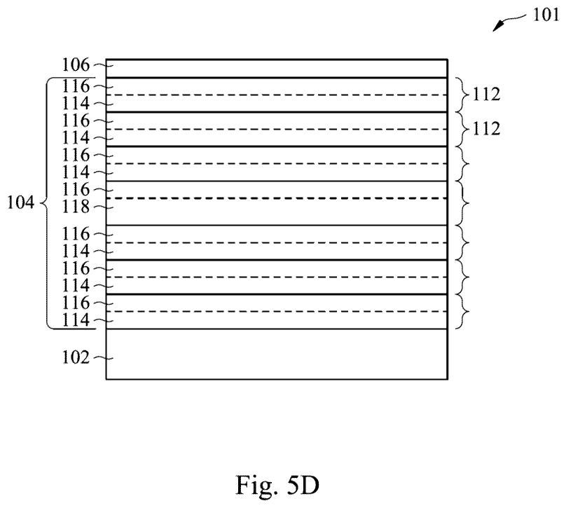

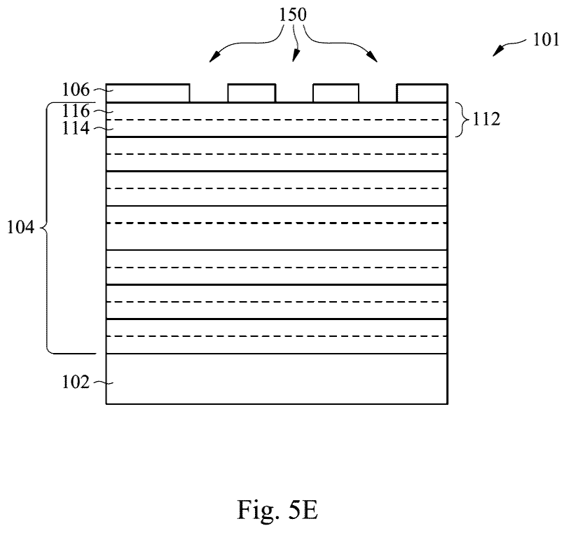

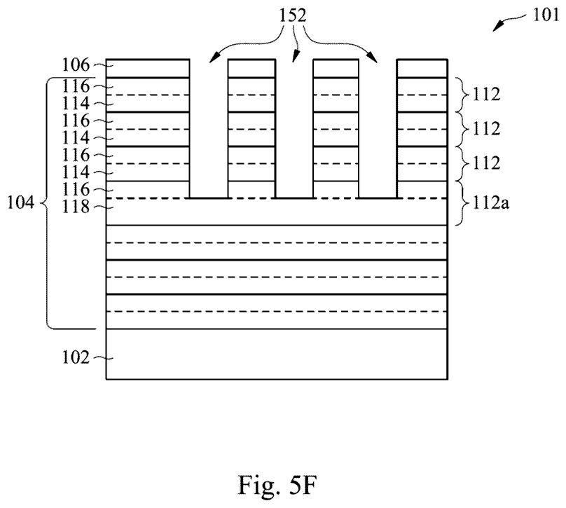

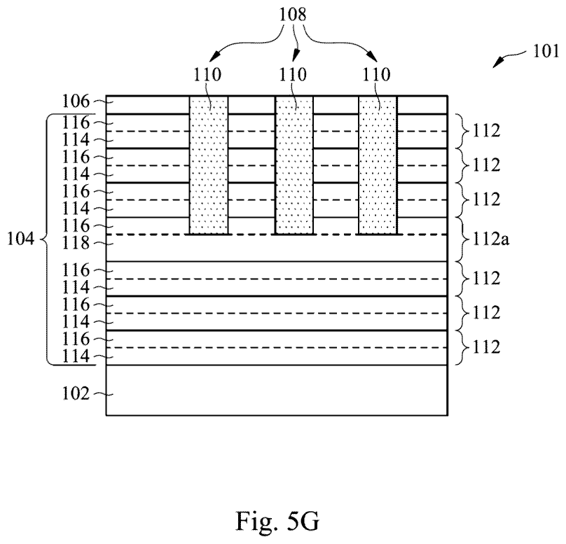

FIGS. 5A-5G are cross-sectional views of the reticle 101 the various stages of processing, in accordance with some embodiments. In some embodiments, the process illustrated in FIGS. 5A-5G can be utilized to form the reticle 101 of FIG. 1A.

In FIG. 5A, the substrate 102 and a plurality of lower pairs of layers 112 of the reflective multilayer 104 have been formed. The materials and thicknesses of the layers 114 and 116 can be as described in relation to FIG. 1A. Each layer 114 can be formed by performing an atomic layer deposition (ALD) process, a chemical vapor deposition (CVD) process, a physical vapor deposition (PVD) process, or other types of deposition processes. Each layer 116 can be formed by performing an ALD process, a CVD process, a PVD process, or other types of deposition processes. Alternating deposition processes can be utilized to deposit alternating layers 114 and 116 until the desired number of pairs 112 have been formed ahead of forming the process assistance pair 112a.

In FIG. 5B, the process assistance pair 112a has been formed over the previously performed pairs 112. The process assistance pair 112a includes the process assistance layer 118 and a layer 116. The process assistance layer 118 can include the materials and thicknesses described in relation to FIG. 1A. The process assistance layer 118 can be formed by ALD, PVD, CVD, or other suitable deposition processes. The layer 116 of the pair 112a is formed on top of the process assistance layer 118 as described in relation to FIG. 5A.

In FIG. 5C, the remaining pairs 112 of layers 114 and 116 have been formed on the pair 112a. The remaining pairs 112 can be formed substantially as described for the initial pairs 112 of FIG. 5A. In FIG. 5C, the reflective multilayer 104 is complete.

In FIG. 5D, the buffer layer 106 has been formed on the top of the reflective multilayer 104. The buffer layer 106 is formed on a top layer 116 of the top pair 112 of the reflective multilayer 104. The buffer layer 106 can include the materials and thicknesses described in relation to FIG. 1A. The buffer layer 106 can be formed by PVD, CVD, ALD, or by other suitable deposition processes.

In FIG. 5E, the buffer layer 106 has been patterned to form openings 150 exposing the top layer 116 of the reflective multilayer 104. The patterning can be accomplished by etching the buffer layer 106 in the presence of the mask that includes the pattern for the openings 150. The pattern of the openings 150 corresponds to the pattern 108 for the absorption structures 110. The buffer layer includes a material that is selectively etchable with respect to the layer 116.

In FIG. 5F, trenches 152 have been formed in the reflective multilayer 104. The trenches 152 are formed below the openings 150 and the buffer layer 106. The trenches 152 can be formed by performing an etching process in the presence of the patterned buffer layer 106. The etching process can include a dry etch, a wet etch, or other types of etching processes. The etching process can include a highly anisotropic etching process that etches selectively in the downward direction. The etching process stops at the process assistance layer 118. Accordingly, the final layer that is etched is the layer 116 of the process assistance pair 112a. The top surface of the process assistance layer 118 corresponds to the bottom of the trenches 152. As described previously, the materials of the layers 114 and 116 are selectively etchable with respect to the material of the layer process assistance layer 118.

In FIG. 5G an absorption material has been deposited in the trenches 152 to form absorption structures 110. The absorption material can include the materials and properties described in relation to FIG. 1A. The absorption material can be deposited by ALD, CVD, PVD, or other suitable processes. After deposition of the absorption material, a planarization process can be performed, such as a chemical mechanical planarization (CMP) process in order to make the top surface of the absorption structures 110 level with the top surface of the buffer layer 106. Additional transparent passivation layers or other types of layers may be deposited on the absorption structures 110 and the buffer layer 106. The pattern of the absorption structures 110 corresponds to the main pattern 108 of the reticle 101. The stage of processing shown in FIG. 5G corresponds to the stage of processing of the reticle 101 of FIG. 1A. Other processes can be utilized to form a reticle 101 with an absorption pattern 108 without departing from the scope of the present disclosure.

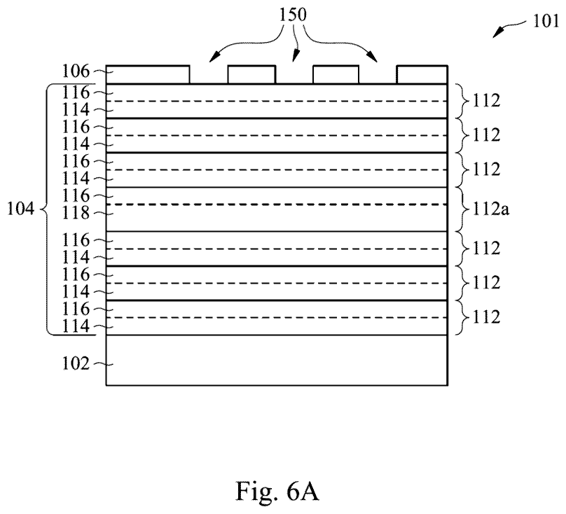

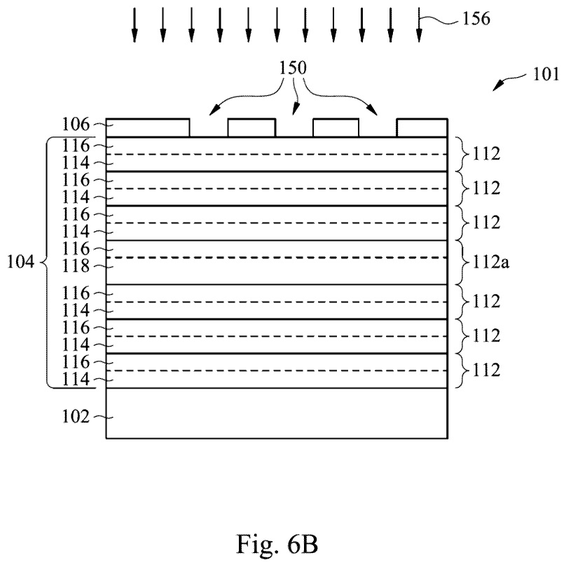

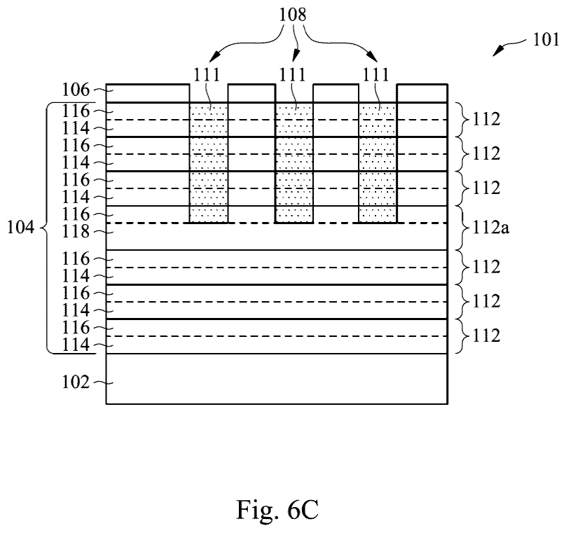

FIGS. 6A-6C are cross-sectional views of the reticle 101 at various stages of processing, in accordance with some embodiments. The process shown in relation to FIGS. 6A-6C can be utilized to form the reticle 101 of FIG. 1B. The stage of processing of FIG. 6A corresponds to the stage of processing shown in FIG. 5E. In particular, the reflective multilayer 104 and the buffer layer 106 have been formed in the buffer layer 106 has been patterned to include openings 150. The materials and thicknesses of the layers shown in FIG. 6A may be as described in relation to FIGS. 1A and 1B.

In FIG. 6B, and implantation process is performed. The implantation process includes bombarding the reticle 101 with dopant species 156. The dopant species 156 can include atoms, ions, or compounds that can be implanted in the exposed portions of the reflective multilayer 104. The dopant species 156 can include Ta, Cr, Pt, Pd, Ir, Ru, Ni, or other suitable dopant species. The material of the buffer layer 106 is selected to prevent the dopant species 156 from passing through to the unexposed portions of the reflective multilayer 104. The materials of the pairs 112 are selected so that the dopant species may be embedded throughout the exposed portions of the reflective multilayer 104. The material of the process assistance layer 118 is selected to prevent the dopant species 156 from implanting below the process assistance layer 118.

In FIG. 6C, absorption structures 111 of an absorption material has been formed in the portions of the reflective multilayer 104 exposed below the openings 150 in the buffer layer 106. The absorption material is formed by the implantation of the dopant species 156 described in relation to FIG. 6B. The absorption material absorbs EUV light. The depth of the absorption structures 111 corresponds to the depth of the top surface of the process assistance layer 118. In FIG. 1C, the reticle 101 corresponds to the reticle 101 of FIG. 1B.

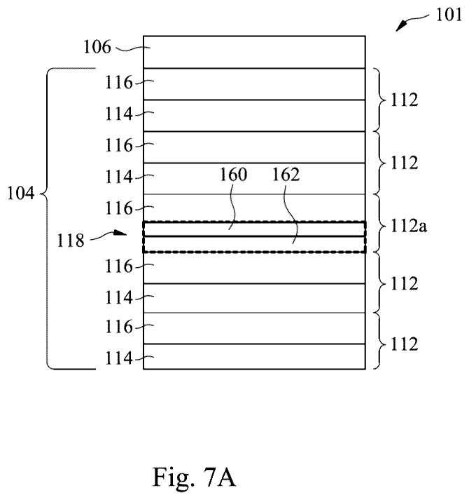

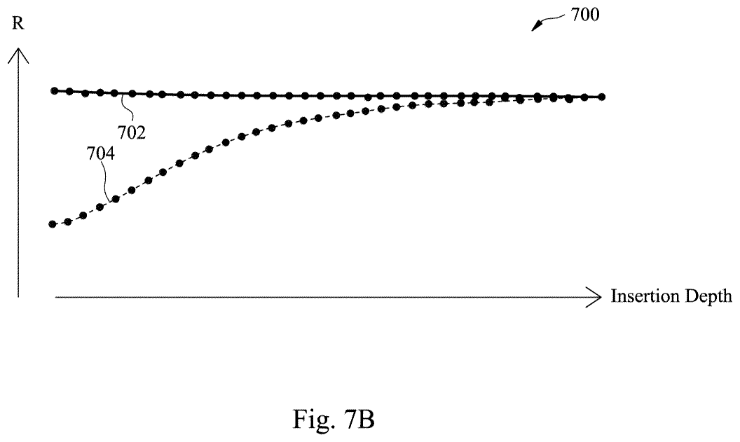

FIG. 7A is a cross-sectional view of a reticle 101, in accordance with some embodiments. The reticle 101 of FIG. 7A may be substantially similar to the reticle 101 of FIGS. 1A or 1B, except that the process assistance layer 118 may include a first sub-layer 160 and a second sub-layer 162. The sub-layer 162 can include ruthenium with a thickness between 0.5 nm and 1.5 nm. The sub-layer 160 can include Tc with a thickness between 1 nm and 2 nm. In an example in which the layer 114 is molybdenum with a thickness of 3 nm and the layer 116 is silicon with a thickness of 4 nm, the sub-layer 162 may include ruthenium with a thickness of 1 nm and the sub-layer 160 may include Tc with a thickness of 1.4 nm. Other thicknesses and materials can be utilized for the layers 160 and 162 without departing from the scope of the present disclosure.

FIG. 7B includes a graph 700 associated with a reticle 101 of FIG. 7A, in accordance with some embodiments. The vertical axis of the graph 700 corresponds to the reflectivity R of the reflective multilayer 104 that includes a process assistance layer 118 including layers 160 and 162. The horizontal axis of the graph 700 corresponds to the insertion depth of the process assistance layer 118 within the reflective multilayer 104.

The graph 700 includes a curve 702 and a curve 704. The curve 702 corresponds to reflectivity for the reflective multilayer 104 in which the process assistance layer 118 is part of a process assistance pair 112a as described in relation to FIGS. 7A. In one embodiment, the curve 704 corresponds to reflectivity for the reflective multilayer 104 in which a process assistance layer 118 is embedded singly between two pairs of layers. As can be seen, the reflectivity is high for most insertion depths for the curve 702. The reflectivity for the curve 704 is considerably lower unless the process assistance layer 118 is embedded very near the bottom of the reflective multilayer 104.

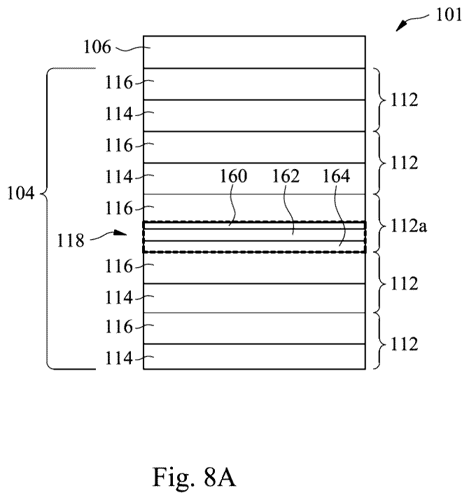

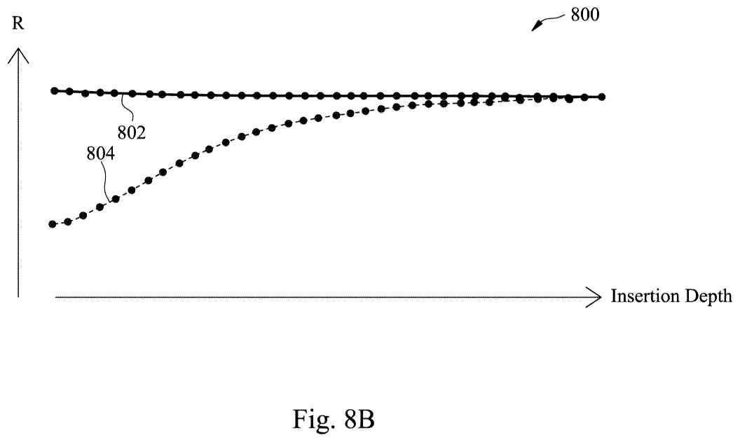

FIG. 8A is a cross-sectional view of a reticle 101, in accordance with some embodiments. The reticle 101 of FIG. 8A may be substantially similar to the reticle 101 of FIGS. 1A or 1B, except that the process assistance layer 118 may include a first sub-layer 160, a second sub-layer 162, and a third sub-layer 164. The sub-layer 164 can include Nb with a thickness between 0.5 nm and 1.5 nm. The sub-layer 162 can include ruthenium with a thickness between 0.5 nm and 1.5 nm. The sub-layer 160 can include Tc with a thickness between 0.2 nm and 1 nm. In an example in which the layer 114 is molybdenum with a thickness of 3 nm and the layer 116 is silicon with a thickness of 4 nm, the sub-layer 164 may include Nb with a thickness of 1 nm, the sub-layer 162 may include ruthenium with a thickness of 1 nm and the sub-layer 160 may include Tc with a thickness of 0.4 nm. Other thicknesses and materials can be utilized for the layers 160, 162, and 164 without departing from the scope of the present disclosure.

FIG. 8B includes a graph 800 associated with a reticle 101 of FIG. 8A, in accordance with some embodiments. The vertical axis of the graph 800 corresponds to the reflectivity R of the reflective multilayer 104 that includes a process assistance layer 118 including layers 160, 162, and 164. The horizontal axis of the graph 800 corresponds to the insertion depth of the process assistance layer 118 within the reflective multilayer 104.

The graph 800 includes a curve 802 and a curve 804. The curve 802 corresponds to reflectivity for the reflective multilayer 104 in which the process assistance layer 118 is part of a process assistance pair 112a as described in relation to FIGS. 8A. In one embodiment, the curve 804 corresponds to reflectivity for the reflective multilayer 104 in which a process assistance layer 118 is embedded singly between two pairs of layers. As can be seen, the reflectivity is high for most insertion depths for the curve 802. The reflectivity for the curve 804 is considerably lower unless the process assistance layer 118 is embedded very near the bottom of the reflective multilayer 104.

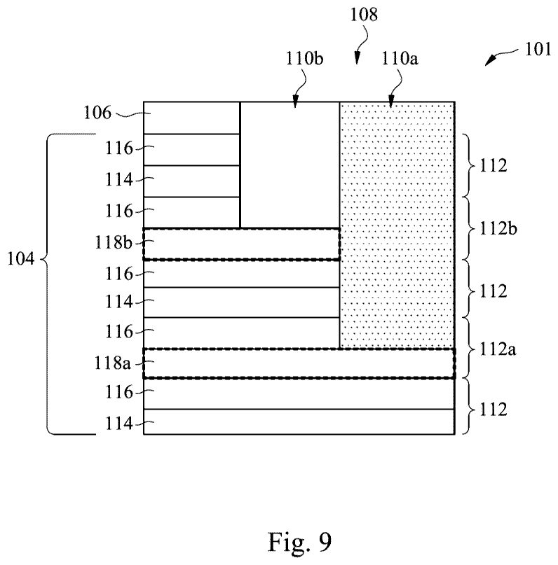

FIG. 9 is a cross-sectional view of a multi tone reticle 101, in accordance with some embodiments. The reticle 101 of FIG. 9 may be substantially similar to the reticle 101 of FIG. 1A or 1B except that there are two process assistance pairs 112a and 112b and there are two types of absorption structures 110a and 110b having different depths. The pair 112a includes the layer 116 and the process assistance layer 118a. The pair 112b includes a layer 116 and a process assistance layer 118b. The materials of the layers 114 and 116 are selectively etchable with respect to the materials of the process assistance layers 118a and 118b. The material of the process assistance layer 118b is selectively etchable with respect to the material of the process assistance layer 118a. In one example, the material of the process assistance layer 118a include silicon dioxide and the material of the process assistance layer 118b includes ruthenium. Other materials can be utilized for the process assistance layers 118a and 118b without departing from the scope of the present disclosure.

In some embodiments, the absorption structure 110b is formed in the manner of the formation of the absorption structures 110 described in relation to FIGS. 5A-5G. However, after formation of the pattern of absorption structures 110b, the buffer layer 106 can again be patterned to form openings for the absorption structures 110a. A second etching process can then be performed that selectively etches the layers 114, 116, and 118b selectively with respect to the layer 118a. The result is that second trenches are formed to a depth of the top surface of the process assistance layer 118a. An absorption material may then be formed in the newly forms trenches to form the absorption structure 110a. The planarization process can then be performed. In some embodiments, the absorption material of the absorption structures 110a is the same as the absorption material of the absorption structures 110b. In some embodiments, the absorption material of the absorption structures 110a is different than the absorption material of the absorption structures 110b. The absorption structure 110a extends to a depth corresponding to the top surface of the process assistance layer 118a. Other processes and materials can be utilized without departing from the scope of the present disclosure.

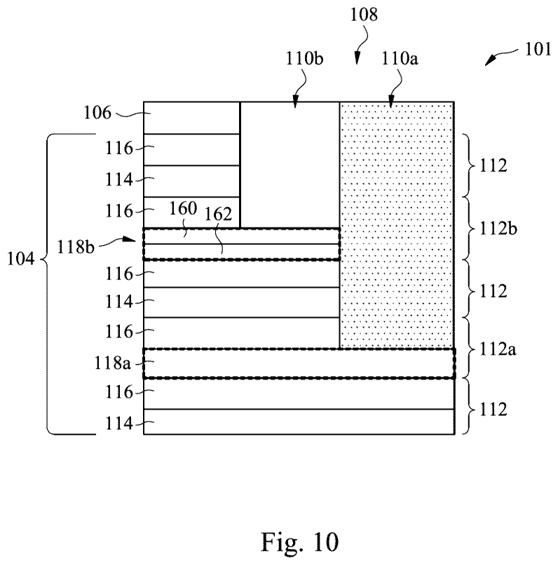

FIG. 10 is a cross-sectional view of a multi-tone reticle 101, in accordance with some embodiments. The reticle 101 of FIG. 10 is substantially similar to the reticle 101 of FIG. 9, except that the process assistance layer 118b includes a first sub-layer 160 and a second sub-layer 162. The layers 160 and 162 can have materials and thicknesses described in relation to FIG. 7A.

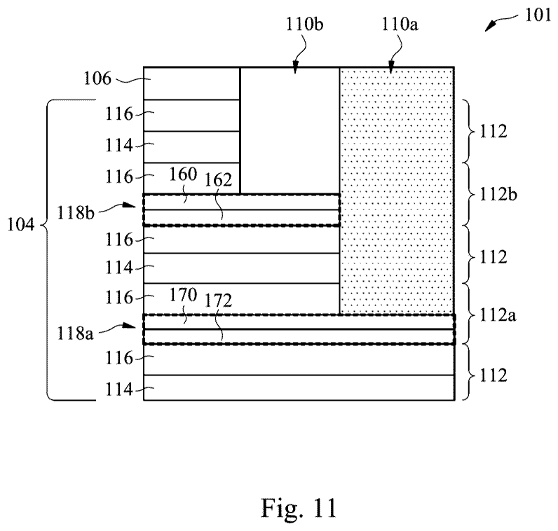

FIG. 11 is a cross-sectional view of a multi tone reticle 101 in accordance with some embodiments. The reticle 101 of FIG. 11 is substantially similar to the reticle 101 of FIG. 10, except that the process assistance layer 118a includes a first sub-layer 170 and a second sub-layer 172. The materials of the layers 170 and 172 can include the same materials described previously for process assistance layers 118. In some embodiments, the first sub-layer 160 includes Tc with a thickness of 1.4 nm. The second sub-layer 162 can include Ru with a thickness of 1 nm. The pair of layers 160 and 162 can used to replace a layer of Mo. The first sub-layer 170 can include K with a thickness of 2 nm. The second sub-layer 172 can include Rb with a thickness of 2 nm. The pair of 170 and 172 can used to replace a layer of Si. Other materials and thicknesses can be utilized without departing from the scope of the present disclosure.

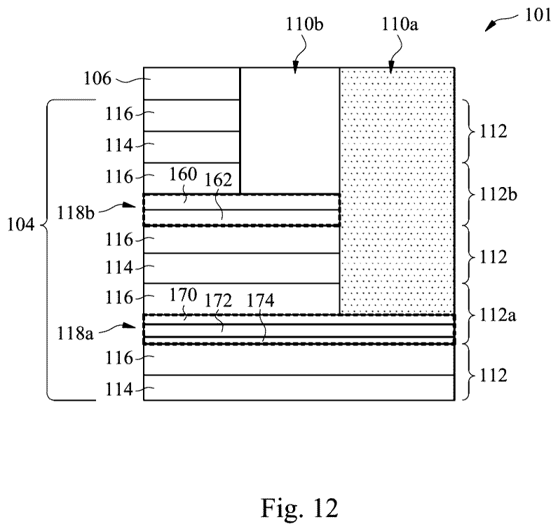

FIG. 12 is a cross-sectional view of a multi tone reticle 101 in accordance with some embodiments. The reticle 101 of FIG. 12 is substantially similar to the reticle 101 of FIG. 11, except that the process assistance layer 118a includes a first sub-layer 170, a second sub-layer 172, and a third sub-layer 174. The materials of the layers 170, 172, 174 can include the same or other materials described for process assistance layers 118. In some embodiments, the first sub-layer 160 includes Tc with a thickness of 1.4 nm. The second sub-layer 162 can include Ru with a thickness of 1 nm. The pair of layers 160 and 162 can used to replace a layer of Mo. The first sub-layer 170 can include Tc with a thickness of 0.4 nm. The second sub-layer 172 can include Rub with a thickness of 1 nm. The third sub-layer 174 can include Nb with a thickness of 1 nm. The layers 170, 172, and 174 can used to replace a layer of Mo. Other materials and thicknesses can be utilized without departing from the scope of the present disclosure.

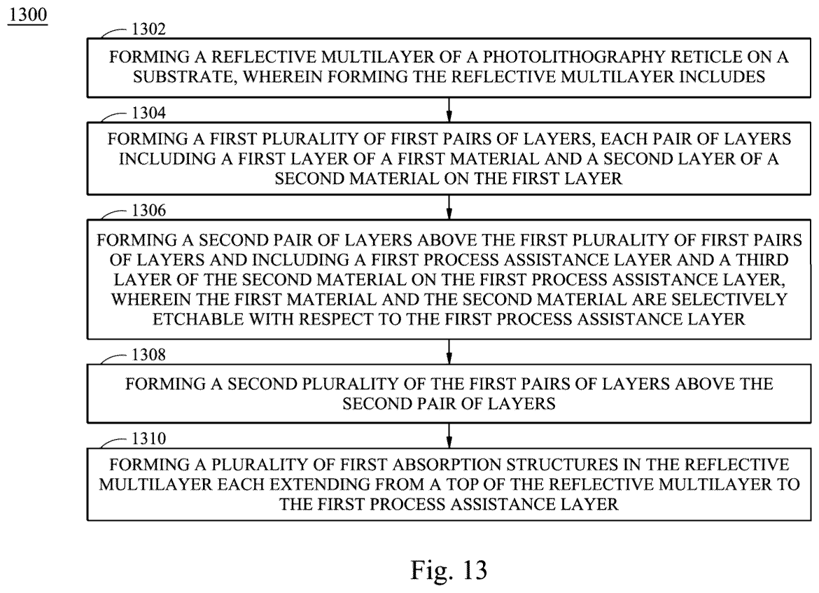

FIG. 13 is flow diagram of a method 1300 for forming a photolithography reticle, in accordance with some embodiments. The method 1300 can utilize processes, components, and systems described in relation to FIGS. 1A-12. At 1302, the method 1300 includes forming a reflective multilayer of a photolithography reticle on a substrate. One example of a reflective multilayer is the reflective multilayer 104 of FIG. 1A. One example of a substrate is the substrate 102 of FIG. 1A. One example of a reticle is the reticle 101 of FIG. 1A. At 1304, forming the reflective multilayer includes forming a first plurality of first pairs of layers, each pair of layers including a first layer of a first material and a second layer of a second material on the first layer. One example of the first pairs are the three lower pairs 112 of FIG. 1A. One example of a first layer is the layer 114 of FIG. 1A. One example of a second layer is the layer 116 of FIG. 1A. At 1306, forming the reflective multilayer includes forming a second pair of layers above the first plurality of first pairs of layers and including a first process assistance layer and a third layer of the second material on the first process assistance layer, wherein the first material and the second material are selectively etchable with respect to the first process assistance layer. One example of a second pair is the second pair 112a of FIG. 1A. One example of a third layer is the layer 116 of the pair 112a of FIG. 1A. One example of a first process assistance layer is the process assistance layer 118 of FIG. 1A. At 1308, forming the reflective multilayer includes forming a second plurality of the first pairs of layers above the second pair of layers. One example of the second pairs are the three upper pairs 112 of FIG. 1A. At 1310, the method 1300 includes forming a plurality of first absorption structures in the reflective multilayer each extending from a top of the reflective multilayer to the first process assistance layer. One example of first absorption structures are the absorption structures 110 of FIG. 1A.

Extreme ultraviolet (EUV) light is used to produce particularly small features due to the relatively short wavelength of EUV light. In particular, high numerical aperture (NA) EUV exposure is adopted for finer resolution. However, in high NA scanners, the depth of focus becomes narrower. Accordingly, the best focus range of printing patterns may need to be carefully controlled. One solution is adopting an EUV photolithography reticle (or mask) with a reflective multilayer that has been etched and in which an absorption material is embedded to reduce reticle induced imaging aberrations known as mask 3D (M3D) effects. One possible solution is to embed an etch-stop layer in the reflective multilayer to stop the etching process prior to formation of the absorption material. However directly inserting an etch-stop layer may degrade the reflectance of the reflective multilayer, thereby reducing the throughput of exposure.

Embodiments of the disclosure are able to embed a process assistance layer, such as an etch-stop layer or an implant-stop layer, in a reflective multilayer of an EUV reticle while retaining high levels of reflectivity of the reflective multilayer. The reflective multilayer includes a plurality of pairs of layers. The pairs of layers are stacked on each other. Most of the pairs of layers have a first layer of a first material stacked on a second layer of a second material. However, in one of the pairs of layers process assistance layers the second layer is not made of the second material but is instead made of a process assistance material that functions as a process assistance layer. In an example in which the process assistance layer is an etch-stop layer, the process assistance layer has a material that is not etched by an etching process that etches the first and second layers of the other pairs of layers. In other words, the first material and the second material of the pairs of layers are selectively etchable with respect to the material of the etch-stop layer. In an example in which the process assistance layer is an implant-stop layer, the process assistance layer includes material that does not permit dopants of a dopant implantation process the past to layers below the process assistance layer.

In one embodiment, an EUV photolithography reticle includes a substrate and a reflective multilayer on the substrate. The reflective multilayer includes a plurality of stacked first pairs of layers, each pair include a first layer of a first material and a second layer of a second material on the first layer. The reflective multilayer includes a second pair of layers between two of the first pairs and including a first process assistance layer and a third layer of the second material on the process assistance layer. The first material and the second material are selectively etchable with respect to the first process assistance layer. The reticle includes a plurality of first absorption structures extending from a top of the reflective multilayer to the first process assistance layer and configured to absorb extreme ultraviolet light.

In one embodiment, a method includes forming a reflective multilayer of a photolithography reticle on a substrate. Forming the reflective multilayer includes forming a first plurality of first pairs of layers, each pair of layers including a first layer of a first material and a second layer of a second material on the first layer and forming a second pair of layers above the first plurality of first pairs of layers and including a first process assistance layer and a third layer of the second material on the first process assistance layer. The first material and the second material are selectively etchable with respect to the first process assistance layer. Forming the reflective multilayer includes forming a second plurality of the first pairs of layers above the second pair of layers. The method includes forming a plurality of first absorption structures in the reflective multilayer each extending from a top of the reflective multilayer to the first process assistance layer.

A photolithography reticle includes a substrate and a reflective multilayer on the substrate. The reflective multilayer includes a first layer of a first material, a second layer of a second material on the first layer, a third layer of a third material on the second layer, a fourth layer of the second material on the third layer, a fifth layer of the first material on the fourth layer, and a sixth layer of the second material on the fifth layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A photolithography reticle, comprising:
a substrate;
a reflective multilayer on the substrate including:
a plurality of stacked first pairs of layers, each pair include a first layer of a first material and a second layer of a second material on the first layer; and
a second pair of layers between two of the first pairs and including a first process assistance layer and a third layer of the second material on the process assistance layer, wherein the first material and the second material are selectively etchable with respect to the first process assistance layer; and
a plurality of first absorption structures extending from a top of the reflective multilayer to the first process assistance layer and configured to absorb extreme ultraviolet light.

2. The photolithography reticle of claim 1, wherein the first process assistance layer includes a first sub-layer and a second sub-layer on the first sub-layer and of a different material than the first sub-layer.

3. The photolithography reticle of claim 1, wherein the first process assistance layer includes a first sub-layer, a second sub-layer on the first sub-layer and of a different material than the first sub-layer, and a third sub-layer of a different material than the first sub-layer and the second sub-layer.

4. The photolithography reticle of claim 1, wherein the reflective multilayer includes a third pair of layers below the second pair of layers and including a second process assistance layer and a fourth layer of the second material on the second process assistance layer, wherein the first material, the second material, and the first process assistance layer are selectively etchable with respect to the second process assistance layer.

5. The photolithography reticle of claim 4, comprising:
a plurality of first trenches extending from the top of the reflective multilayer to the first process assistance layer, wherein the first absorption structures are within the first trenches; and
a second trench extending from the top of the reflective multilayer to the second process assistance layer.

6. The photolithography reticle of claim 5, comprising a second absorption structure in the second trench.

7. The photolithography process of claim 4, wherein the first process assistance layer includes a plurality of first sub-layers.

8. The photolithography reticle of claim 7, wherein the second process assistance layer includes a plurality of second sub-layers.

9. The photolithography reticle of claim 8, wherein there is a different number of first sub-layers than second sub-layers.

10. The photolithography reticle of claim 1, wherein the first material is molybdenum, the second material is silicon, and the first process assistance layer includes ruthenium.

11. The photolithography reticle of claim 1, wherein the first material is molybdenum, the second material is silicon, and the first process assistance layer includes silicon dioxide.

12. A method, comprising:
forming a reflective multilayer of a photolithography reticle on a substrate, wherein forming the reflective multilayer includes:
forming a first plurality of first pairs of layers, each pair of layers including a first layer of a first material and a second layer of a second material on the first layer;
forming a second pair of layers above the first plurality of first pairs of layers and including a first process assistance layer and a third layer of the second material on the first process assistance layer, wherein the first material and the second material are selectively etchable with respect to the first process assistance layer; and
forming a second plurality of the first pairs of layers above the second pair of layers; and
forming a plurality of first absorption structures in the reflective multilayer each extending from a top of the reflective multilayer to the first process assistance layer.

13. The method of claim 12, wherein forming the plurality of first absorption structures includes:
forming a plurality of first trenches in the reflective multilayer extending from the top of the reflective multilayer to the first process assistance layer; and
depositing a first absorption material in the first trenches.

14. The method of claim 13, wherein the first process assistance layer is an etch-stop layer for the first trenches.

15. The method of claim 13, wherein forming the reflective multilayer includes forming a third pair of layers between two of the first pairs of layers of the first plurality of first pairs of layers and including a second process assistance layer and a third layer of the second material on the second process assistance layer, the method comprising:
forming a second trench extending from the top of the reflective multilayer to the second process assistance layer; and
forming a second absorption structure in the second trench.

16. The method of claim 12, wherein forming the plurality of first absorption structures includes:
depositing a buffer layer on the reflective multilayer;
forming openings in the buffer layer exposing the reflective multilayer; and
forming the first absorption structure by implanting dopants into the reflective multilayer below the openings in the buffer layer.

17. The method of claim 15, wherein the first process assistance layer inhibits the dopants from implanting in the first pairs of layers below the first process assistance layer.

18. A photolithography reticle, comprising:
a substrate;
a reflective multilayer on the substrate and including:
a first layer of a first material;
a second layer of a second material on the first layer;
a third layer of a third material on the second layer;
a fourth layer of the second material on the third layer;
a fifth layer of the first material on the fourth layer; and
a sixth layer of the second material on the fifth layer.

19. The photolithography reticle of claim 18, comprising a plurality of absorption structures extending from a top of the reflective multilayer through the sixth, fifth, and fourth layers and terminating at the third layer.

20. The photolithography reticle of claim 18, wherein the first layer and the fifth layer have a same first thickness, wherein the second layer, the fourth layer, and the sixth layer have a same second thickness, and the third layer has a third thickness different than the first thickness.
